(19) United States
(12) Patent Application Publication
(10) Pub. No.: US 2026/0262321 A1
(43) Pub. Date: Sep. 3, 2026

(54) PROCESS FOR THE FORMATION OF A PEROVSKITE LAYER IN PARTICULAR FOR A PHOTOVOLTAIC CELL

(71) Applicant: SINGULUS TECHNOLOGIES AG, Kahl am Main (DE)

(72) Inventor: Mirza CORDA, Maisach (DE)

(73) Assignee: SINGULUS TECHNOLOGIES AG, Kahl am Main (DE)

(21) Appl. No.: 19/489,920

(22) PCT Filed: Jul. 22, 2024
(86) PCT No.: PCT/EP2024/070791

§ 371 Date: Dec. 4, 2025

(30) Foreign Application Priority Data
Aug. 1, 2023 (DE) 10 2023 120 382.7

(51) Int. Cl. H10F 71/10; H10F 77/169

(52) U.S. Cl. CPC H10F 71/107; H10F 77/1698

(57) ABSTRACT

A method for forming a perovskite layer on a carrier substrate and a method for manufacturing a solar cell having such a perovskite layer. The method includes providing the carrier substrate coated with a first perovskite precursor layer composed of a first perovskite precursor, coating the first perovskite precursor layer on the carrier substrate with a second perovskite precursor layer by applying a solution, which contains a second perovskite precursor forming the second perovskite precursor layer, to a roll, and transferring the solution as a solution film to the first perovskite precursor layer by unrolling the roll along the first perovskite precursor layer, and heating the first perovskite precursor layer together with the solution film above a predetermined reaction temperature limit to initiate a chemical reaction between the first perovskite precursor and the second perovskite precursor.

### FIELD

The present invention relates to a method for forming a perovskite layer. The invention further relates to a method for manufacturing a solar cell having a perovskite layer formed in this way.

### TECHNICAL BACKGROUND

Perovskite layers, i.e., thin layers of perovskite material, may have interesting electrical and optical properties, among other things, because of which they are suitable for a wide variety of applications.

In particular, solar cells have recently been developed in which an absorber layer of perovskite material is used for absorbing light and for photovoltaic conversion of energy contained in the light into electrical energy. Such so-called perovskite solar cells promise high efficiencies with low material costs and simple manufacture.

Various methods are known for forming perovskite layers, in particular for solar cells.

For example, chemical substances which may react with one another to form a perovskite material and which are also referred to herein as perovskite pre-product, perovskite precursors or perovskite starting materials may be applied to a substrate in a single process step and then chemically reacted there, for example, by supplying energy in the form of, for example, heat. In such a single-stage process, the perovskite layer precursors may be vapor-deposited onto a substrate, for example, in a common vapor deposition process. However, such vapor deposition processes are often difficult to implement on an industrial scale, require complex apparatuses and/or are cost-intensive. Alternatively, wet-chemical deposition processes for forming a perovskite layer in a single-stage process have been proposed. However, technical difficulties and/or high costs often also impede an industrial implementation of in these methods.

Alternatively, perovskite precursors may be applied to a substrate in a two-stage process before they are then again chemically reacted. In this case, first a first perovskite precursor layer is applied to a substrate and then a second perovskite precursor layer is applied over it.

In order to form the two perovskite precursor layers, different technologies may again be used.

For example, a perovskite precursor layer may be formed by depositing chemical substances suitable for this purpose by means of physical vapor deposition (PVD) or chemical vapor deposition (CVD). However, complex apparatuses are generally necessary for this purpose, wherein high costs and/or low throughputs associated therewith often make such methods of industrial implementation uninteresting.

Alternatively, at least one of the perovskite precursor layers may be formed by means of wet-chemical methods. In this case, use of different wet-chemical deposition methods is conceivable.

For example, a so-called spin coating is often used on a laboratory scale in order to apply a viscous solution, in which the substances required for the perovskite precursor are contained, to a rotating substrate and then distribute it there to form a perovskite layer precursor layer of homogeneous thickness on account of acting centrifugal forces. However, such an approach may usually only be used for coating small-area substrates and is not particularly interesting for industrial implementation for forming perovskite layers because of the lack of mass suitability.

As an alternative, perovskite layers may also be applied wet-chemically with the aid of so-called extrusion slot dies. Such methods are also referred to as slot-die-coating. In this case, a solution which should be sufficiently viscous and in which the substances required for the perovskite precursor are again contained is extruded through a wide slot die onto a surface of a substrate. However, a relatively high outlay in terms of apparatus required for this purpose and restrictions on the viscous solutions which may be used in this case do not make industrial implementation of such deposition methods for forming perovskite layers appear interesting.

In addition, in the two wet-chemical deposition methods mentioned above, the starting materials are frequently dissolved in solvents such as, for example, dimethylformamide, which are relatively hazardous hazardous substances which are, for example, flammable and/or toxic. This may make industrial implementation of the methods mentioned more difficult, for example, on account of high costs or necessary complex apparatuses. In particular, when designing a plant to be used for this purpose, many safety aspects such as, for example, taking account of regulations (e.g. ATEX) may lead to an increase in cost. The solvents themselves are also frequently expensive, as a result of which production costs of the overall process may be increased.

In a further approach, the starting materials are applied to a substrate upon being dissolved in a solvent by a spraying method, which is also referred to as spray coating.

However, aerosols are generally generated here which, on the one hand, may be complicated to remove by suction and/or on account of which a proportion of the starting materials used does not pass into the perovskite layer to be generated, as a result of which an efficiency of the deposition is reduced.

### SUMMARY

There may therefore be a need for an alternative approach with the aid of which a perovskite layer may be formed and with the aid of which at least some of the problems mentioned above of previous approaches may be avoided or reduced. In particular, there may be a need for a method with the aid of which a perovskite layer may be produced with low costs, low outlay in terms of apparatus and/or in a manner which may be easily implemented industrially. In addition, there may be a need for a method for manufacturing a solar cell in which such a method is used for forming a perovskite layer.

The stated needs may be at least partially satisfied with the subject matter of one of the independent claims of the present application. Advantageous embodiments are specified in the dependent claims and in the following description.

According to a first aspect of the present invention, a method for forming a perovskite layer on a carrier substrate is described. The method has at least the following process steps, preferably in the specified order:
(i) providing the carrier substrate coated with a first perovskite precursor layer composed of a first perovskite precursor, and
(ii) coating the first perovskite precursor layer on the carrier substrate with a second perovskite precursor layer by
   applying a solution, which contains a second perovskite precursor forming the second perovskite precursor layer, to a roll, and
   transferring the solution as a solution film, which forms the second perovskite precursor layer, to the first perovskite precursor layer by unrolling the roll along the first perovskite precursor layer, and
   (iii) heating the first perovskite precursor layer together with the solution film above a predetermined reaction temperature limit in order to initiate a chemical reaction between the first perovskite precursor and the second perovskite precursor.

According to a second aspect of the present invention, a method for manufacturing a solar cell is described. The method has at least the following process steps, preferably in the specified order:
forming a perovskite layer on a surface of a carrier substrate, which has been coated beforehand with a first perovskite precursor layer, by means of the method according to one of the preceding claims, and
forming electrical contacts for discharging electrical charge carriers from the perovskite layer.

Embodiments of the invention may be considered, inter alia and without restricting the invention, to be based on ideas or observations described below.

In the introduction, a basic concept for embodiments of the invention described herein will be explained briefly, wherein this explanation is to be interpreted as merely roughly summarizing and not limiting the invention:

As already indicated, the aim is to provide an advantageous and in particular industrially usable process for forming perovskite layers, for example, for manufacturing solar cells. For this purpose, a two-stage process is proposed herein. A first perovskite precursor layer is formed in any desired manner and applied beforehand on a carrier substrate. A second perovskite precursor layer is then applied in a second process step on the carrier substrate provided with this first perovskite precursor layer. For this purpose, a specific wet-chemical process is selected, in which a solution, which contains the second perovskite precursor, is applied to a roll and is then transferred to the first perovskite precursor layer in the form of a solution film by unrolling the roll along the first perovskite precursor layer. As explained in more detail further below, the roll may be formed in particular as an absorbent roll in order to be able to absorb the solution efficiently and release it again in a controlled manner. In addition, a harmless and inexpensive solvent, such as in particular water, may be used for the solution. After the solution film has been applied in this way, the first perovskite precursor layer is heated together with the solution film above a predetermined reaction temperature limit, above which a chemical reaction occurs between the first and the second perovskite precursor, whereupon they form the perovskite layer desired.

The proposed approach may be implemented here with a technically relatively simple plant. In addition, hazardous, harmful and/or expensive solvents may be dispensed with. Furthermore, no aerosols generally arise in the proposed roll-on process.

Possible features of configurations of the invention and advantages to be achieved therewith are described in detail below.

The perovskite layer to be formed with the method described herein may be produced in principle with any desired dimensions. For example, an area of the perovskite layer may be between a few square millimeters up to several square meters. Preferably, an area of the perovskite layer may be between 5 cm² and 5 m², more preferably between 200 cm² and 2 m². In this case, a layer thickness may be between 1 nm and 1 mm, preferably between 100 nm and 1 μm. In this case, the perovskite layer is generally not self-supporting, but rather is supported by a carrier substrate.

In principle, the carrier substrate may have any desired dimensions and consist of any desired material. For example, the carrier substrate may have the same area dimensions as the perovskite layer to be formed thereon. However, the carrier substrate may also have a larger area than the perovskite layer to be formed, so that the latter covers only partial areas of the carrier substrate. The carrier substrate generally has a significantly greater thickness than the perovskite layer. For example, the thickness of the carrier substrate is usually greater than 0.1 mm, often greater than 0.5 mm, greater than 1 mm or even greater than 3 mm, but generally less than 2 cm or less than 1 cm.

A material and a geometry of the carrier substrate may be selected in such a way that, on the one hand, it supports the perovskite layer sufficiently mechanically in order to be able to withstand the forces acting on the perovskite layer during operation. On the other hand, the carrier substrate should be able to withstand the conditions occurring during the formation of the perovskite layer, such as, for example, temperatures, attacks by chemicals used, etc. Furthermore, a coefficient of thermal expansion of the carrier substrate should not differ excessively from that of the perovskite layer formed thereon. In practice, thin glass panes have proven to be suitable for the carrier substrate for many applications. In examples, the glasses themselves may have electrically conductive coatings. However, carrier substrates composed of semiconductor material, in particular in the form of silicon plates or wafers, may also be used. As described in more detail further below, for example, an already finished processed solar cell, for example a solar cell constructed from a silicon wafer, may serve as a carrier substrate. In principle, however, carrier substrates composed of other materials are also conceivable, for example composed of plastic, ceramic, metal, etc.

The carrier substrate is coated beforehand with a first perovskite precursor layer. Any desired coating methods may be used for this purpose. For example, the first perovskite precursor layer may be deposited with the aid of PVD methods or CVD methods. The carrier substrate preprocessed by the coating with the first perovskite precursor layer is then provided for the method described herein.

A second perovskite precursor layer is then applied to the first perovskite precursor layer. For this purpose, an application process is used in which a solution is applied to the first perovskite precursor layer with the aid of a roll and is distributed thereon in a planar manner and as homogeneously as possible.

In this case, the solution contains the second perovskite precursor, which is dissolved in a liquid solvent and/or mixed with the latter. In this case, the solution may be saturated to a certain extent with the second perovskite precursor, for example to an extent of more than 10%, more than 30%, more than 60%, more than 80%, more than 90%, more than 95% or even with complete saturation or even supersaturation. The solution may be temperature-controlled to room temperature or ambient temperature. Alternatively, the solution may be heated to a higher temperature or cooled to a lower temperature in relation to the ambient temperature.

The solution is first applied to the roll and then transferred from the latter as a solution film to the first perovskite precursor layer on the carrier substrate. For this purpose, the roll provided with the solution is moved along the perovskite precursor layer, so that, during unrolling, it transfers the solution stored on or in it at least partially as a solution film to the surface of the first perovskite precursor layer.

The first perovskite precursor layer covered in this way with the solution film is then heated in a targeted manner. In particular, heating above a predetermined reaction temperature limit is carried out in this case. This reaction temperature limit may depend in a material-specific manner on the properties of the first and the second perovskite precursor and represents that temperature above which a chemical reaction occurs between the two perovskite precursors, so that they ultimately form the desired perovskite layer. This reaction temperature limit is usually above 50° C., above 60° C. or above 70° C., but usually below 150° C., below 130° C., below 110° C. or below 90° C. In this case, evaporation of the solvent contained in the solution occurs simultaneously during the heating mentioned.

According to one embodiment, the solution is aqueous. An aqueous solution is usually easy to handle and inexpensive to provide. In particular, the aqueous solution should be free of harmful, hazardous and/or difficult to dispose of chemicals.

For example, according to one embodiment, the solution may contain only water and the second perovskite precursor. In particular, it has been observed that chemicals which have a high solubility in water may be used as second perovskite precursors.

Accordingly, an easy-to-handle and inexpensive mixture of water and such a perovskite precursor to which no other chemicals or at least no significant amounts of other chemicals have been added may be used as solution.

According to one embodiment, the second perovskite precursor is inorganic. In other words, the second perovskite precursor is free of carbon compounds. It has been recognized that inorganic substances are particularly well suited for use in the method described herein. In addition, it has been recognized that perovskite layers with inorganic substances may have advantageous properties such as, for example, a high chemical stability, a high radiation resistance and thus a long lifetime.

In particular, according to a further concretized embodiment, the second perovskite precursor may be a cesium halide salt. Cesium halide salts have been recognized as particularly suitable for use in the solution in the method described herein. In this case, bromine may preferably be used as the halogen fraction. For example, cesium bromide (CsBr) may be used as the cesium halide salt. Alternatively, however, other halogen fractions such as, for example, chlorine or iodine or mixtures of different cesium halide salts may also be used.

According to one embodiment, the first perovskite precursor is also inorganic. As a result, in particular the entire perovskite layer may be constructed from inorganic material. The entire perovskite layer may thus be chemically stable, radiation-resistant and/or long-lasting.

In particular, according to a further concretized embodiment, the first perovskite precursor may be a lead halide salt. In this case, bromine, chlorine or iodine may again be used as the halogen fraction. The lead halide salt may be, for example, lead dibromide (PbBr₂).

According to one embodiment, the roll may be provided with absorbent material at least on an outer circumferential surface. In other words, the roll may be configured in such a way that it may absorb the solution at least in an outer volume region adjacent to the outer circumferential surface thereof. The solution applied to the roll thus does not form, or at least does not exclusively form, a film which forms along the outer circumferential surface of the roll, as would be the case, for example, with pure plastic rolls having a smooth surface. Instead, the solution applied to the roll is at least partially, preferably to a predominant fraction or even completely, sucked into the absorbent material of the roll and thus absorbed within the volume of the roll within the outer circumferential surface.

A manner in which the absorbency of the material of the roll is formed may in this case determine a manner in which and in which amounts the solution is absorbed therein. In this case, the roll may consist completely of the absorbent material. Alternatively, the roll may have a core made of another material, to which the absorbent material is then applied as an outer absorbent layer along the circumferential surface of the roll formed overall. In this case, the outer absorbent layer may have, for example, a thickness which makes up at least 5%, preferably at least 10%, at least 20% or even at least 30% of the roll diameter. The roll diameter may be, for example, in a range from 0.5 cm to 20 cm, preferably a range from 1 cm to 10 cm or a range from 2 cm to 5 cm.

According to a concretized embodiment, the absorbent material (17) may be porous. In other words, the absorbent material may have pores into which the solution may be incorporated. For example, the absorbent material may have a porosity of more than 5%, preferably more than 10%, more than 20%, more than 30% or even more than 50%. In this case, the porosity indicates the ratio of pore volume to total volume. The absorbent material is preferably of open-pored form, i.e. adjacent pores are connected to one another. In particular, the absorbent material should be open-pored on the outer circumferential surface of the roll. A roll formed with such a porous absorbent material may also be referred to as a sponge roll.

According to one embodiment, the roll may be formed with a polymer material. Such a polymer material may simply be formed as an absorbent and in particular porous material. For example, the roll may be formed with polyurethane foam or coated superficially. Alternatively, the absorbent material may be formed with other foams, cellulose or other synthetic polymers.

According to one embodiment, the solution may be applied to the roll at a first position which is spaced apart from a second position at which the roll contacts the first perovskite precursor layer. In this case, an extrusion device may be pressed onto an outer circumferential surface of the roll in the circumferential direction between the first position and the second position in such a way that an amount of solution which is carried along by the roll during the rolling-on process and is applied to the first perovskite precursor layer is adjustably limited.

In other words, an amount of solution which is carried along by the roll and is absorbed in particular in the absorbent material of the roll may be adjusted and thus limited by a specific extrusion device being used to extrude a possibly excessively applied volume of solution from the roll in a targeted manner.

In this case, the extrusion device presses against the outer circumference of the roll at a third position which differs both from the first position at which the solution is applied to the roll and from the second position at which the roll bears against the perovskite precursor layer and which is spaced apart from the first position and from the second position along the circumference of the roll and lies between these two positions in the circumferential direction.

By extruding solution from the roll at the third position, only a reduced volume of solution is then absorbed in the roll at least in a fourth position which lies behind the third position in the circumferential direction and with respect to a direction of rotation of the roll. This reduced volume may be influenced or controlled by adjusting the contact pressure of the extrusion device.

Since the amount of solution which is transferred to the first perovskite precursor layer during the unrolling of the roll generally depends on the amount of solution carried along overall in the roll, this amount of transferred solution may be adjusted and limited in this way. In addition, a contact pressure with which the roll is pressed against the carrier substrate and/or a flow rate with which the solution is applied to the roll also influence the amount of transferred solution, so that these variables may also be adjusted in a targeted manner, wherein generally attention should be paid to achieving homogeneity of wetting of the roll in the longitudinal direction. As a result, it may ultimately be avoided that an excessive amount of solution and therefore an excessively thick solution film is transferred to the first perovskite precursor layer.

The extrusion device may be formed, for example, as a further roll which is pressed against the outer circumferential surface of the roll which carries along the solution. This further roll may be rigid and have a hard, smooth circumferential surface and/or be non-absorbent. Alternatively, however, it may also be formed with a flexible surface and/or with an absorbent surface. In this case, the two rolls may unroll on one another.

Alternatively, the extrusion device may also be configured as a type of doctor blade which is pressed against the outer circumferential surface of the roll and slides along the latter.

A pressing-on pressure or a pressing-on force between the extrusion device and the roll may optionally be adjustable. By adjusting this pressing-on pressure, the amount of solution which remains in the absorbent layer of the roll after extrusion may be influenced or adjusted.

In addition or alternatively, a pressing-on pressure or a pressing-on force between the roll and the first perovskite precursor layer may be adjustable.

According to one embodiment, an excess of solution applied to the roll may be extracted from the roll with the aid of a suction device. In this case, the suction device may be arranged adjacent to the outer circumferential surface of the roll and may be configured to extract excess solution there. The suction device may be arranged in particular at a fifth position which is situated along the circumference of the roll between the first position at which the solution is applied to the roll and the third position at which the extrusion device presses part of the applied solution out of the roll again. By extracting excess solution, it may be avoided, inter alia, that it flows, for example, at undesired points, i.e., for example, flows beyond a lateral edge of the roll.

With the aid of the method according to the first aspect of the invention, a perovskite layer may be formed which may then be used when manufacturing a solar cell according to the second aspect of the invention.

In this case, the solar cell may be formed as a pure perovskite solar cell. For this purpose, electrical contacts in the form of electrodes must additionally be attached to the perovskite layer formed, with the aid of which electrical charge carriers which are produced by absorption of light in the perovskite layer may be discharged and fed to an external circuit. In addition to the electrical contacts, further layers or components may be formed on the perovskite layer. In this case, the method described herein is suitable in particular for manufacturing perovskite solar cells based on inorganic perovskite layers.

According to a further embodiment, the carrier substrate may comprise a first solar cell, wherein the perovskite layer is formed together with the electrical contacts as a second solar cell. In other words, the carrier substrate itself may be a solar cell or have a solar cell, so that a further solar cell may then be formed on this existing solar cell with the aid of the perovskite layer formed thereon produced by the method described herein. In this case, the first solar cell may be referred to as a bottom solar cell and the second solar cell may be referred to as a top solar cell, wherein both solar cells together form a tandem solar cell.

In particular, the first solar cell may be a silicon solar cell, preferably a solar cell formed on the basis of a silicon wafer. Such silicon solar cells may be produced with technologies which have been established for a long time, have high efficiencies and be very reliable. On such a silicon solar cell, a perovskite solar cell may be formed as a top solar cell. In this case, the two solar cells complement one another well with regard to their respective absorption spectra.

Alternatively, the first solar cell may be a thin-film solar cell, for example on the basis of a III-V semiconductor. As a further example, the first solar cell may be a CdTe solar cell or a CIGS solar cell.

It is pointed out that possible advantages and configurations of embodiments of the invention are described herein in part with respect to a method according to the invention for forming a perovskite layer and in part with respect to a method for manufacturing a solar cell having such a perovskite layer. A person skilled in the art recognizes that the described features may be transferred, adapted, exchanged or modified in a suitable manner in order to arrive at further embodiments of the invention.

### BRIEF DESCRIPTION OF THE DRAWINGS

Embodiments of the invention are described below with reference to the appended drawings, wherein neither the drawings nor the description are to be interpreted as limiting the invention.

FIG. 1(a)-(d) show successive stages of a method according to one embodiment of the invention.

FIG. 2 shows a roller arrangement as may be used in a method according to one The figures are merely schematic and not true to scale. Identical reference signs designate identical or identically acting features in the various figures.

### DETAILED DESCRIPTION

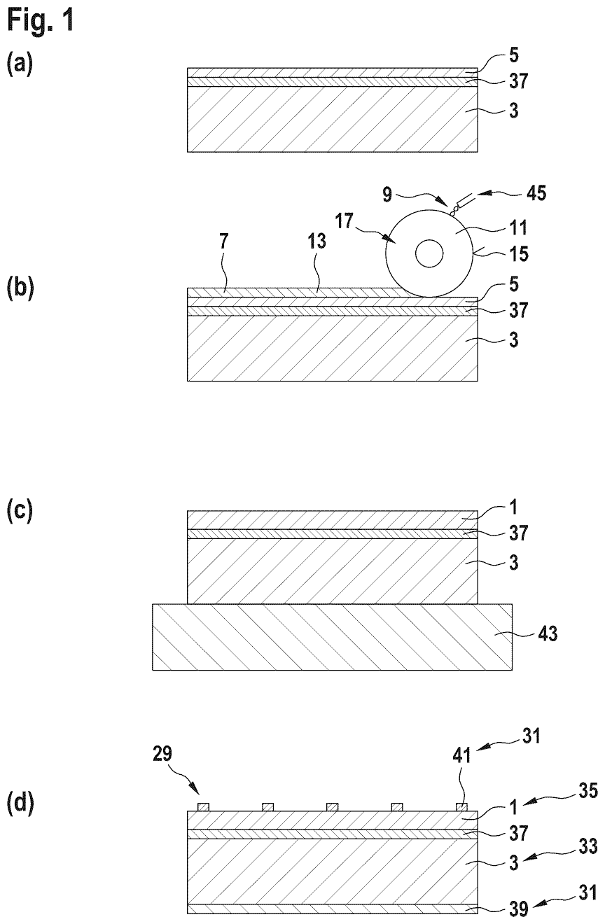

FIG. 1 shows successive stages of a method for forming a perovskite layer 1, with the aid of which a solar cell 29 is ultimately formed.

In a first step (see FIG. 1(a)), a carrier substrate 3 is provided, which has been coated beforehand with a first perovskite precursor layer 5. A glass substrate is used, for example, as the carrier substrate 3. A layer made of a lead halide salt in the form of a layer made of PbBr2 has been applied beforehand to this as the first perovskite precursor layer 5 by evaporation.

In the present case, a further layer in the form of an electrically conductive conduction layer 37 has been formed between the carrier substrate 3 and the first perovskite precursor layer 5. In addition or alternatively, further layers, for example in the form of an adhesive layer, a buffer layer or the like, may be interposed.

In a second step (see FIG. 1(b)), a solution 9 made of cesium halide salt dissolved in water in the form of, for example, CsBr is applied to a roller 11. In this case, the solution 9 may be fed continuously via a feed device 45. In the example illustrated, the roll 11 is formed as a sponge roll and has absorbent material 17 along its outer circumferential surface 15. During unrolling of the roll 11 along the first perovskite precursor layer 5 on the carrier substrate 3, part of the solution 9 absorbed in the roll 11 is transferred to the surface of the first perovskite precursor layer 5 and forms a solution film 13 there. A second perovskite precursor layer 7 then forms from this solution film 13 after the water has volatilized from the solution 9.

In a third step (see FIG. 1(c)), the carrier substrate 3 is heated together with the first perovskite precursor layer 5 and the solution film 13 with the aid of a heater 43 above a predetermined reaction temperature limit of, for example, more than 60° C., in order thereby to initiate a chemical reaction between the perovskite precursors contained in the two perovskite precursor layers 5, 7. In this case, the perovskite precursors react to form a perovskite and thereby form the desired perovskite layer 1 on the carrier substrate 3. The heater 43 may heat the carrier substrate 3 together with the perovskite precursor layer 5 and the solution film 13 from one side or from two opposite sides, for example from above, from below or both from above and from below. For this purpose, for example, a plurality of heating elements may be provided which are arranged along a travel path along which the carrier substrate 3 is successively displaced. For example, the heating elements may be arranged in a segmented manner between transport rolls which convey the carrier substrate. The carrier substrates may possibly be transported with the aid of a continuous furnace, along the travel path of which heating elements are arranged. The various heating elements may be set to different temperatures, for example in order to implement different functionalities such as predrying, crystallization, etc.

In order ultimately to manufacture a solar cell 29 with the perovskite layer 1 formed in this way, electrical contacts 31 in the form of an electrical rear contact 39 and an electrical front contact 41 are produced in a fourth step (see FIG. 1(d)), which electrically contact the perovskite layer 1 on opposite sides. In the example illustrated in a simplified manner, for this purpose, the rear contact 39 may be applied to a side of the carrier substrate 3 opposite the perovskite layer 1 and may be electrically connected to the previously produced conductive layer 37 (not illustrated). Alternatively and usually preferably for practical applications, a rear contact 39 may be formed which acts directly on the conductive layer 37 which is located between the carrier substrate 3 and the perovskite layer 1. In this case, the rear contact 39 may be provided, for example, in the form of a metal layer. The front contact 41 may be provided in the form of a multiplicity of thin finger-like metal contacts. Alternatively or in addition, the front contact 41 may be formed with the aid of an electrically conductive, transparent layer. Overall, a solar cell 29 in the form of a perovskite solar cell may be formed in this way. Possibly, the side facing the sun may also be that side which is covered with the glass substrate. In this case, the metal layer 41 may act as a rear contact and possibly be formed over the entire area.

Alternatively, the carrier substrate 3 may be formed, instead of with a glass substrate, by an already preprocessed first solar cell 33. For example, this first solar cell 33 may be an efficient wafer-based silicon solar cell. The perovskite layer 1 may then be produced on a front side surface of this first solar cell 33 and in this case form a second solar cell 35.

The two solar cells 33, 35 are electrically connected to one another via the conductive layer 37 formed therebetween and may thereby form overall a solar cell 29 in the form of a tandem solar cell.

It is pointed out that both the method steps and the structures produced thereby have been illustrated and described merely in a greatly simplified manner. In real implementation, further method steps may be used and/or further structures may be produced, for example, in the form of additional layers, electrodes or the like.

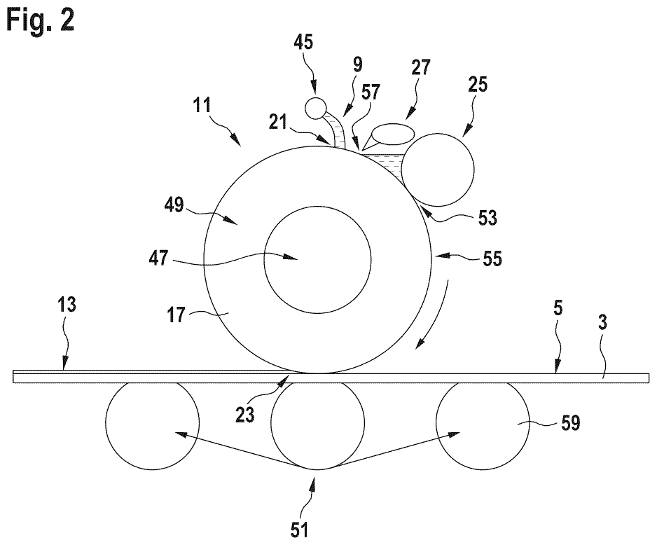

FIG. 2 illustrates details of the transfer of the solution 9 to the carrier substrate 3 with the aid of the roll 11.

The solution 9 is applied continuously to the roll 11 at an upper first position 21 with the aid of the feed device 45. In this case, the roll 11 is formed as a sponge roll and has a fixed roll core 47 which is surrounded by a sponge layer 49 of absorbent material 17 such as, for example, porous polyurethane. The solution 9 is thus at least partially absorbed in the sponge layer 49 and moved along with the rotating roll 11.

At a lower second position 23, the roll 11 touches the carrier substrate 3 together with the first perovskite precursor layer 5 already deposited thereon. In this case, the roll 11 is pressed at least slightly against the carrier substrate 3, so that part of the solution 9 absorbed therein is pressed out of the sponge layer 49 and transferred to the upper surface of the first perovskite precursor layer 5.

In this case, the roll 11 and the carrier substrate 3 are moved relative to one another, for example by the carrier substrate 3 being moved through under the roll 11 with the aid of a conveying device 51 and the roll 11 unrolling along the upper surface of the perovskite precursor layer 5. In the example illustrated, the conveying device 51 is formed with a plurality of conveying rollers 59. Alternatively, other types of conveying devices 51 may also be used, for example a conveyor belt. As a result of the relative movement between the roll 11 and the carrier substrate 3, the solution film 13 on the surface of the first perovskite precursor layer 5 is formed by the solution 9 emerging from the roll 11.

In order to be able to influence the amount of transferred solution 9 or the thickness of the solution film 13, an extrusion device 25 is provided at a third position 53. In this case, the third position 53 is located between the first position 21 and the second position 23 in the circumferential direction. In the example illustrated, the extrusion device 25 is formed as a fixed roll and may also be referred to as a squeeze roll. The extrusion device 25 presses locally onto the sponge layer 49, so that part of the solution 9 absorbed therein is pressed out of the latter and therefore does not pass to a fourth position 55 below the extrusion device 25 and ultimately to the second position 23. Accordingly, a degree of saturation of the sponge roll may be controlled with the aid of the extrusion device 25 and in particular by adjusting a contact force or a contact pressure of this extrusion device 25. As a result, the amount of solution 9 deposited onto the first perovskite precursor layer 5 may ultimately be controlled.

In addition, a suction device 27 is provided at a fifth position 57 between the first position 21 and the third position 53, with the aid of which suction device an excess of solution 9 applied to the roll 11 may be extracted.

Finally, it should be pointed out that terms such as “having”, “comprising”, etc. do not exclude any other elements or steps and terms such as “a” or “an” do not exclude a multiplicity. Furthermore, it should be pointed out that features or steps which have been described with reference to one of the above exemplary embodiments may also be used in combination with other features or steps of other exemplary embodiments described above. Reference signs in the claims should not be regarded as a restriction.

### LIST OF REFERENCE SIGNS

1 perovskite layer
3 carrier substrate
5 first perovskite precursor layer
7 second perovskite precursor layer
9 solution
11 roll
13 solution film
15 outer circumferential surface
17 absorbent material
21 first position
23 second position
25 extrusion device
27 suction device
29 solar cell
31 electrical contacts
33 first solar cell
35 second solar cell
37 conduction layer
39 electrical rear contact
41 electrical front contact
43 heater
45 feed device
47 roll core
49 sponge layer
51 conveying device
53 third position
55 fourth position
57 fifth position
59 conveying roller

1-14. (canceled)

15. A method for forming a perovskite layer on a carrier substrate, comprising:
providing the carrier substrate coated with a first perovskite precursor layer composed of a first perovskite precursor,
coating the first perovskite precursor layer on the carrier substrate with a second perovskite precursor layer by
applying an aqueous solution, which contains an inorganic second perovskite precursor forming the second perovskite precursor layer, to a roll, wherein the roll is provided with absorbent, porous material at least on an outer circumferential surface, and
transferring the solution as a solution film, which forms the second perovskite precursor layer, to the first perovskite precursor layer by unrolling the roll along the first perovskite precursor layer, and
heating the first perovskite precursor layer together with the solution film above a predetermined reaction temperature limit in order to initiate a chemical reaction between the first perovskite precursor and the second perovskite precursor.

16. The method according to claim 15,
wherein the solution contains only water and the second perovskite precursor.

17. The method according to claim 15,
wherein the second perovskite precursor is a cesium halide salt.

18. The method according to claim 15,
wherein the first perovskite precursor is inorganic.

19. The method according to claim 18,
wherein the first perovskite precursor is a lead halide salt.

20. The method according to claim 15,
wherein the roll is formed with a polymer material.

21. The method according to claim 15,
wherein the solution is applied to the roll at a first position which is spaced apart from a second position at which the roll contacts the first perovskite precursor layer, and
wherein an extrusion device is pressed onto an outer circumferential surface of the roll in the circumferential direction between the first position and the second position in such a way that an amount of solution which is carried along by the roll during the rolling-on process and is applied to the first perovskite precursor layer is adjustably limited.

22. The method according to claim 15,
wherein an excess of solution applied to the roll is extracted from the roll with the aid of a suction device.

23. A method for manufacturing a solar cell, comprising
forming a perovskite layer on a surface of a carrier substrate, which has been coated beforehand with a first perovskite precursor layer, by means of the method according to claim 15, and
forming electrical contacts for discharging electrical charge carriers from the perovskite layer.

24. The method according to claim 23,
wherein the carrier substrate comprises a first solar cell and wherein the perovskite layer is formed together with the electrical contacts as a second solar cell.
